(19) United States
(12) Patent Application Publication
(10) Pub. No.: US 2022/0389572 A1
(43) Pub. Date: Dec. 8, 2022

(54) METHOD FOR COATING A COMPONENT

(71) Applicants: WIELAND-WERKE AG, Ulm (DE); WIELAND WICOATEC GMBH, Ulm (DE)

(72) Inventors: Jan SZABO, Neresheim (DE); Till MERKEL, Neu-Ulm (DE); Gerd SPERLE, Lonsee (DE)

(21) Appl. No.: 17/774,287

(22) PCT Filed: Nov. 6, 2019
(86) PCT No.: PCT/EP2019/000305

§ 371 Date: May 4, 2022

(51) Int. Cl. C23C 16/40; C23C 16/448

(52) U.S. Cl. CPC C23C 16/402; C23C 16/4488

(57) ABSTRACT

A method for coating a component including the following steps: providing a gas phase containing at least one tetra-alkoxy silane as first silicon-containing precursor, at least one functionalised silicic acid ester with a phenyl, vinyl, allyl, thiol, amino, acryloxy, epoxy, nitrile, isocyanate, isothiocyanate or methacrylate group as second silicon-containing precursor, at least one catalyst, water and inert gas, the silicon-containing precursors being added in metered fashion to the gas phase separately from one another and separately from the water and the catalyst, chemically reacting the first silicon-containing precursor with water in the gas phase so ss to form first reaction products, chemically reacting the second silicon-containing precursor with water in the gas phase so as to form second reaction products, depositing the reaction products on the component. The reaction products of all precursors together form a coating on the component based on amorphous silicon dioxide.

The invention relates to a method for coating the surface of a component by means of chemical deposition from the gas phase, wherein silicon-containing precursors are used.

Coating of surfaces with a layer of amorphous SiO₂ is known. Such coatings can be applied by means of a CVD process or by means of a sol-gel process.

Patent specification U.S. Pat. No. 3,556,841 A describes a CVD process for applying such a coating. This involves directing a gas mixture composed of tetraethoxysilane or ethyltriethoxysilane, an organic acid and nitrogen onto the surface of the component to be coated. The component is kept at a temperature of 300 to 600° C. so that a layer of amorphous SiO₂ is deposited from the gas mixture onto the surface of the component.

Document WO 2011/026565 A1 describes a particularly efficient CVD process for forming a coating composed of amorphous SiO₂. In this process, the reactive gas mixture is circulated in the reaction space and back mixed with fresh precursor. This allows a particularly high yield of the substances used.

Furthermore, patent specification U.S. Pat. No. 5,763,018 A discloses that, as an alternative to tetraethoxyorthosilane, it is also possible to use octamethylcyclotetrasiloxane, tetrapropoxysilane or tetramethylcyclotetrasiloxane as precursors in a CVD process for applying a dielectric coating. The precursors mentioned are suitable for specific applications. However, they cannot fulfill every requirement currently placed on a coating of components.

In many applications, a coating should constitute a durable barrier to counteract mass transfer between the substrate and the surroundings. This should inhibit, in some cases, mass transfer from the substrate to the surroundings, for example the release of metal ions, and should prevent, in other cases, the penetration of gases or liquids, in particular of corrosive gases or liquids, into the surface of the substrate. A coating therefore needs to exhibit a high and long-term impermeability to specific substances, depending on the application. The impermeability must be reliably maintained even under extreme and/or changing ambient conditions, such as the temperature.

In other applications, the coating should serve as an adhesion promoter between the substrate and another substance. In these applications, too, the function of the coating must be able to be permanently ensured under extreme and/or changing ambient conditions.

Ever greater requirements in many respects are therefore placed on the functionality of the coating.

The invention is based on the object of specifying a method for applying an improved coating onto surfaces.

The invention is represented by the features of claim 1. The further dependent claims relate to advantageous embodiments and developments of the invention.

The invention encompasses a method for coating a component, wherein the method comprises the following steps:
providing a gas phase containing at least one tetraalkoxysilane as first silicon-containing precursor, at least one functionalized silicic ester having a phenyl, vinyl, allyl, thiol, amino, acryloxy, epoxide, nitrile, isocyanate, isothiocyanate or methacrylate group as second silicon-containing precursor, at least one catalyst, water and inert gas, optionally hydrogen, or consisting of these substances, wherein the silicon-containing precursors are metered into the gas phase separately from one another and separately from the water and the catalyst,
chemically reacting the first silicon-containing precursor with water in the gas phase to form first reaction products,
chemically reacting the second silicon-containing precursor with water in the gas phase to form second reaction products,
depositing the reaction products onto the component, wherein the reaction products of all precursors together form a coating based on amorphous silicon dioxide on the component.

The invention relates to a coating method which uses, as precursors, at least one tetraalkoxysilane and a substance or multiple substances from the group of the functionalized silicic esters. A tetraalkoxysilane may be understood as meaning a substance of the general formula Si(ORᵢ)₄, where Rᵢ are four independent organic hydrocarbon groups, in particular alkyl groups. The hydrocarbon groups Rᵢ may be entirely or partially identical or else be different. The central silicon atom is thus bonded to a total of four hydrocarbon groups via four oxygen atoms. The tetraalkoxysilane is preferably a tetraalkoxysilane of symmetrical construction, such as tetraethyl orthosilicate (TEOS) or tetramethyl orthosilicate (TMOS).

The at least one functionalized silicic ester is a silicic ester having at least one Si—C bond. At least one silicon atom of the silicic ester is thus directly bonded to at least one organic radical. This organic radical has a phenyl, vinyl, allyl, thiol, amino, acryloxy, epoxide, nitrile, isocyanate, isothiocyanate or methacrylate group.

The precursors are converted to the gas phase and transported into a reaction space by means of a stream of inert or reducing gas, for example nitrogen or a mixture of nitrogen and up to 5% by volume of hydrogen (forming gas). The gas phase also contains water and a catalyst in addition to the silicon-containing precursors. Suitable catalysts are acids and bases. The catalyst is preferably a carboxylic acid, particularly preferably acetic acid. In the reaction space, a chemical reaction of the silicon-containing precursors with water takes place in the gas phase. The temperature of the gas phase, the concentration of the substances or the degree of mixing of the substances can influence the speed of the reaction. The silicon-containing reaction products of the precursors are deposited onto the surface of the component to be coated, where they form the coating by crosslinking. The component is situated in the reaction space. The surface of the component can preferably at least partially be made from a ceramic, for example glass or Al₂O₃, from a high-temperature plastic, for example polyether ether ketone, polyetherimide, or polyethersulfone, and/or a metal, for example from copper, a copper alloy, aluminum, aluminum alloy, steel or stainless steel.

The pressure of the gas phase in the method is preferably between 500 and 1200 hPa. The method can therefore be carried out in a pressure range that does not require any great apparatus complexity. It is also possible in this pressure range to deposit uniform and dense layers even onto components having complex outer contours.

The method is preferably carried out in a temperature range between 250° C. and 350° C. The reaction speed in this temperature range is sufficiently high to achieve short process times. On the other hand, the process temperature is still low enough so as to avoid undesirable consequences for the component, such as a change in strength.

With regard to further method parameters, particularly with regard to the fundamental composition of the gas phase, reference is made to the statements in document WO 2011/026565 A1. The disclosure of said document is incorporated in full, but in a non-limiting manner, into the description of the present invention.

The properties of the coating may be varied through the selection of the precursors. Investigations on which the invention is based have shown that the use of one or more functionalized silicic esters as additional precursor in such a coating method makes it possible to influence the properties of the deposited coating in a targeted manner. Such a silicic ester is used here in the method as additional precursor together with at least one tetraalkoxysilane. The tetraalkoxysilane provides the chemical building blocks from which the coating is primarily constructed, that is to say the basic building blocks for the amorphous silicon dioxide. The silicic ester used as additional, second silicon-containing precursor contains at least one organic group not present in the tetraalkoxysilane. The additional silicic ester is functionalized by this group. Both the tetraalkoxysilane and the additional, second silicon-containing precursor react in the gas phase with water, and the reaction products of all silicon-containing precursors contribute to the formation of the coating by crosslinking. The reaction products of the tetraalkoxysilane form the basic structure of the coating (matrix). The reaction products of the functionalized silicic ester are incorporated into this basic structure without breaking the silicon-carbon bond. The organic groups of the functionalized silicic ester alter the network constructed from the reaction products of the tetraalkoxysilane and thereby cause the coating to have special properties.

The silicon-containing precursors are supplied to the gas phase separately from one another and separately from the water and the catalyst. This may for example be carried out by separately evaporating the individual substances. The individual reactive components therefore only come into contact with one another in the gas phase, and not while they are in the liquid phase. The inert gas present in the gas phase dilutes the reactive substances and thus slows down the reaction thereof. As a result, the reaction becomes controllable and a uniform layer that is uninterrupted and thereby dense can be deposited.

If the reactive substances, in particular the different precursors, were already mixed with one another in the liquid phase, then an uncontrolled preliminary reaction would take place, which would lead to undesirable formation of particles. This is of particular importance at the preferred pressure level of the method, since the boiling point of the precursors at this pressure level is relatively high. The precursors would already rapidly react with one another in the liquid phase at these temperatures. This is prevented by separate metering of the reactive components, in particular the silicon-containing precursors.

The tetraalkoxysilane and the at least one functionalized silicic ester are used in the gas phase in a molar mixing ratio from 95:5 to 50:50. The tetraalkoxysilane is therefore usually added in excess based on the amount of substance, whereas the at least one functionalized silicic ester, or all functionalized silicic esters as a whole, represents the minority in the mixture of the silicon-containing substances. The excess of the tetraalkoxysilane means that the coating is predominantly constructed from the reaction products of the tetraalkoxysilane.

A coating produced using the method according to the invention contains, depending on the precursor used, at least one constituent containing a phenyl, vinyl, allyl, thiol, amino, acryloxy, epoxide, nitrile, isocyanate, isothiocyanate or methacrylate group. The constituents present in the coating form a ceramic matrix having organic fractions. What is simultaneously formed here is an organoceramic hybrid material consisting of amorphous silicon dioxide having the organic groups mentioned incorporated therein. Said organic groups alter the basic structure of amorphous silicon dioxide and as a result give the coating specific properties. The coating is compact and dense.

In particular, the advantages achieved with the invention are that the incorporation of specific organic groups into the basic structure of the coating, formed essentially from amorphous silicon dioxide, makes it possible to influence and therefore control the properties of the coating in a specific manner. A coating composed of amorphous silicon dioxide is already highly advantageous per se on account of its chemical resistance. By the incorporation of the organic groups mentioned, this advantageous property can be combined with additional advantageous properties. The coating can therefore be adapted to whatever is the task. The chemical resistance of a coating composed of amorphous silicon dioxide is thus supplemented with further advantageous properties.

The use of a silicic ester having a phenyl group means that phenyl groups are incorporated into the coating. These large steric groups disrupt the ceramic network, whereby mechanical properties of the coating, such as the modulus of elasticity, are modified and may therefore be adapted to whatever are the requirements. The silicon-phenyl bond furthermore represents an optimum compromise between necessary adaptation of the mechanical characteristics and simultaneous assurance of the thermal stability of the system. Such a coating can therefore be used even in the case of high-temperature applications.

When using a silicic ester having a vinyl group, the vinyl group forms, on the surface of the coating, unsaturated groups which are able to form a chemical bond with other suitable substances and thus increase the adherence of these substances on the surface. The same effect occurs when using silicic esters having an allyl group.

When using silicic esters having a thiol group, the thiol groups form stable metal-sulfur bonds with certain metals, for example copper or silver. Layer adherence on this substrate is increased as a result. Thiol groups on the layer surface also make said surface available for subsequent synthetic modification.

When using silicic esters having an acryloxy group, acrylate groups important for adhesive bonding with acrylic or methacrylic materials are formed on the surface.

When using silicic esters having an epoxide group, epoxides are incorporated, with ring opening, into the ceramic matrix, thereby making it possible to increase the organic fraction of the coating. The layer then behaves in a similar manner to a polymer. The epoxides and their reaction products help to form chemical bonds with alcohols, amines, thiols, etc. on the surface.

When using silicic esters having a nitrile group, it is observed that nitriles are converted to carboxylic acid during the process. The resultant acid functions on the surface improve the corrosion resistance of the coating.

When using silicic esters having an isocyanate group, these groups, during the reaction of the precursor, are hydrolyzed to form carbamide groups (C—N group), which then decarboxylate to form amino groups. These amino groups lead to quickening of the gas phase reaction, and so greater layer thicknesses can be obtained with the same reaction time. This higher rate of layer formation is advantageous if the coating is intended to prevent the migration of metal ions of the substrate into other media, such as drinking water. Furthermore, isocyanate, amino and urea groups, which are formed secondarily, are incorporated into the coating. The coating becomes more elastic as a result and can therefore better withstand mechanical stress.

When using a silicic ester having an isothiocyanate group, silylthiourethane structures are formed in the ceramic matrix of the coating. Said structures help to form a stable metal-sulfur bonds when bonding to metals. Furthermore, the formation of the silylthiourethane structures leads to better crosslinking of the ceramic matrix, as a result of which there is a higher proportion of quaternary crosslinked silicate units in the matrix. Since the thiourethane that forms is more chemically reactive than the corresponding urethane, it can be better functionalized after the synthesis.

The functional groups (phenyl, vinyl, allyl, thiol, amino, acryloxy, epoxide, nitrile, isocyanate, isothiocyanate or methacrylate group) present in the coating can be qualitatively detected and quantitatively determined by means of infrared spectroscopy methods. The respective functional group is identified on the basis of characteristic vibration frequencies, or on the basis of the characteristic wavenumbers, measured in cm⁻¹, corresponding to the vibration frequencies.

Furthermore, the functional groups (phenyl, vinyl, allyl, thiol, amino, acryloxy, epoxide, nitrile, isocyanate, isothiocyanate or methacrylate group) present in the coating can be qualitatively detected and quantitatively determined by means of solid-state nuclear magnetic resonance spectroscopy. The respective functional group is identified on the basis of the characteristic shift in the resonance frequency for such groups.

The following functionalized silicic esters may preferably be used as precursor: tris(2-methoxyethoxy)vinylsilane, allyltrimethoxysilane, phenyltrimethoxysilane, triethoxyvinylsilane or diphenyldimethoxysilane. These silicic esters contain a phenyl, vinyl or allyl group.

Furthermore, the following functionalized silicic esters may preferably be used as precursor, alone or in combination with one or more of the abovementioned precursors: (3-aminopropyl)trimethoxysilane, (3-mercaptopropyl) trimethoxysilane, bis[3-(triethoxysilyl)propyl]amine, N-[3-(trimethoxysilyl)propyl]butylamine, tris(dimethylamino)silane or N-[3-(dimethoxymethylsilyl)propyl]ethylendiamine. These silicic esters contain a thiol or amino group.

In addition, the following functionalized silicic esters may preferably be used as precursor, alone or in combination with one or more of the abovementioned precursors: (3-cyanopropyl)dimethylchlorosilane, (3-glycidoxypropyl) trimethoxysilane, 3-isocyanatopropyltrimethoxysilane, 3-thiocyanatopropyltriethoxysilane, 3-trimethoxysilylpropyl methacrylate or (3-acryloxypropyl)trimethoxysilane. These silicic esters contain an acryloxy, epoxide, nitrile, isocyanate, isothiocyanate or methacrylate group.

In a preferred configuration of the invention, the volume fraction of all functionalized silicic esters as a whole in the gas phase can be at least 0.05% by volume, in particular at least 0.15% by volume, and at most 0.62% by volume, in particular at most 0.45% by volume. These concentration ranges prove to be favourable or to be particularly favourable for forming a coating having the desired properties.

In the case of the coating method, in the gas phase, the volume ratio of all functionalized silicic esters as a whole to the catalyst can preferably be at least 0.08 and at most 0.12. The catalyst interacts both with the tetraalkoxysilane and with the functionalized silicic esters. The quantitative ratio between catalyst and functionalized silicic esters therefore needs to be adapted. The stated range has proven to be advantageous for achieving a uniform coating that is uninterrupted and thus dense.

In the gas phase, the amount of substance of all functionalized silicic esters can preferably be 20 to 40%, particularly preferably 25 to 35%, of the amount of substance of all silicon-containing precursors. If the proportion of the functionalized silicic esters is below 20%, then it has little influence on the coating. At proportions above 40%, the basic structure of the coating is relatively highly disrupted by the functional groups and it is not always possible to ensure the fundamental properties of the coating, such as the corrosion resistance.

In a preferred configuration of the method, the gas phase can contain a further functionalized silicic ester having a phenyl, vinyl, allyl, thiol, amino, acryloxy, epoxide, nitrile, isocyanate, isothiocyanate or methacrylate group as third silicon-containing precursor. The third silicon-containing precursor differs from the second silicon-containing precursor. This third silicon-containing precursor reacts in the gas phase with water to form third reaction products. These third reaction products are deposited on the component and, together with the reaction products of the other silicon-containing precursors, form the coating. The addition of a further silicon-containing precursor makes it possible to even better adapt the properties of the coating to the boundary conditions and the task.

In a particularly preferred embodiment of the method, the gas phase can contain a silicic ester having a methacrylate group as second silicon-containing precursor and a silicic ester having an amino group and/or isocyanate group as third silicon-containing precursor. When simultaneously using a silicic ester having a methacrylate group and a silicic ester containing an amino group and/or isocyanate group, these two substances react with one another. The disilane thus formed and the methacrylate and amino groups are incorporated into the coating. They are therefore available on the surface of the coating. On account of their chemical properties, they are able to form chemical bonds with organic materials, such as coating materials or adhesives, said bonds improving the adherence to the base material. As a result, the coating acts as an adhesion promoter between the organic material and the metallic substrate. It is of particular importance in this embodiment of the invention that the silicon-containing precursors are metered into the gas phase separately from one another so as in particular to prevent a premature, uncontrolled reaction of the two functionalized silicic esters with each another.

The invention will be explained in more detail on the basis of the following exemplary embodiment.

In the production of plate heat exchangers, metal solder foils, for example of copper or nickel, are placed between stamped stainless steel plates that are stacked on top of one another. The stainless steel plates are then soldered to one another, by heating the stack up to the melting point of the solder foils. The task was to reduce the release of copper and nickel ions into drinking water in the case of such a plate heat exchanger. For test purposes, the surfaces coming into contact with water in the case of such plate heat exchangers were coated by means of a process based on the CVD process described in document WO 2011/026565 A1. The process gas used during the coating of the plate heat exchangers contained approximately 93% by volume of forming gas, consisting of 95% by volume of nitrogen and 5% by volume of hydrogen, as well as acetic acid, water and, as silicon-containing precursors, tetramethyl orthosilicate and 3-isocyanatopropyltrimethoxysilane. The overall proportion of all silicon-containing precursors in the gas phase was between 1.0% and 1.5% by volume. In the gas phase, the volume ratio of the 3-isocyanatopropyltrimethoxysilane to the acetic acid was approximately 1:10. Furthermore, the amount of substance of the 3-isocyanatopropyltrimethoxysilane based on the entire amount of substance of the silicon-containing precursors, i.e. the sum of tetramethyl orthosilicate and 3-isocyanatopropyltrimethoxysilane, was approximately 30%. Acetic acid was added in excess based on the volume fraction of water, but not more than in the ratio of 2:1.

During the coating process, the temperature in the reactor was 300° C., the pressure was 1013 hPa and the carrier gas flow was 0.4 m³/h. The coating time was 3 hours.

As a reference, heat exchangers of the same type were coated with a reference coating by means of a CVD process. In this case, only tetramethyl orthosilicate was used as precursor, without any functionalized silicic ester. The rest of the test conditions were identical.

The effectiveness of the coating was tested by subjecting sections of the coated heat exchanger plates and sections of uncoated heat exchanger plates to an accelerated corrosion test. For this purpose, the sections were dipped into sulfuric acid (25% by weight concentration) at 65° C. After a test duration of 3 hours, the concentration of the copper and nickel ions in the acid was determined. In the case of the samples coated using the method according to the invention, the concentration of the metal ions was only 0.2% of the value that was determined for the uncoated samples. In the case of the coated reference samples, the concentration of the metal ions was approximately 11% of the value that was determined for the uncoated samples. The coating according to the invention thus reduced the release of metal ions to 1/500 of the ion release of the uncoated samples and to 1/55 of the ion release of the coated reference samples. Furthermore, cracks appeared in the coatings of the reference samples, which can be attributed to the low level of elasticity of the reference coating.

In the case of the samples coated using the method according to the invention, the amino group formed from the reaction of the cyanate group with water is detectable in the infrared spectrum of the coating by means of its characteristic signal at wavenumbers of 3100 cm⁻¹, 1651 cm⁻¹ and 1556 cm⁻¹. The methylene group originating from the CH₂ chain that connects the nitrogen to the silicon in the 3-isocyanatopropyltrimethoxysilane is identifiable on the basis of characteristic signals at 2937 cm⁻¹ and 600 cm⁻¹.

1. A method for coating a component, wherein the method comprises the following steps:
providing a gas phase containing at least one tetraalkoxysilane as first silicon-containing precursor, at least one functionalized silicic ester having a phenyl, vinyl, allyl, thiol, amino, acryloxy, epoxide, nitrile, isocyanate, isothiocyanate or methacrylate group as second silicon-containing precursor, at least one catalyst, water and inert gas, optionally hydrogen, or consisting of these substances, wherein the silicon-containing precursors are metered into the gas phase separately from one another and separately from the water and the catalyst,
chemically reacting the first silicon-containing precursor with water in the gas phase to form first reaction products,
chemically reacting the second silicon-containing precursor with water in the gas phase to form second reaction products,
depositing the reaction products onto the component, wherein the reaction products of all precursors together form a coating based on amorphous silicon dioxide on the component.

2. The method as claimed in claim 1, wherein the volume fraction of all functionalized silicic esters as a whole in the gas phase is at least 0.05% by volume and at most 0.62% by volume.

3. The method as claimed in claim 1, wherein, in the gas phase, the volume ratio of all functionalized silicic esters as a whole to the catalyst is at least 0.08 and at most 0.12.

4. The method as claimed in claim 1, wherein, the amount of substance of all functionalized silicic esters is 20 to 40% of the amount of substance of all silicon-containing precursors.

5. The method as claimed in claim 1, wherein the gas phase contains a further functionalized silicic ester having a phenyl, vinyl, allyl, thiol, amino, acryloxy, epoxide, nitrile, isocyanate, isothiocyanate or methacrylate group as third silicon-containing precursor,
and in that the third silicon-containing precursor chemically reacts in the gas phase with water to form third reaction products.

6. The method as claimed in claim 5, wherein the gas phase contains a silicic ester having a methacrylate group as second silicon-containing precursor and a silicic ester having an amino group and/or isocyanate group as third silicon-containing precursor.
